(19) United States
(12) Patent Application Publication
(10) Pub. No.: US 2026/0053046 A1
(43) Pub. Date: Feb. 19, 2026

(54) SEMICONDUCTOR PACKAGE AND METHOD OF MANUFACTUING THE SAME

(71) Applicant: Samsung Electronics Co., Ltd., Suwon-si (KR)

(72) Inventors: Seonho Lee, Suwon-si (KR); Seungwoo Park, Suwon-si (KR); Seonghwa Bae, Suwon-si (KR)

(21) Appl. No.: 19/289,184

(22) Filed: Aug. 4, 2025

(30) Foreign Application Priority Data
Aug. 19, 2024 (KR) 10-2024-0110765

(51) Int. Cl. H01L 23/00; H01L 21/56; H01L 25/00

(52) U.S. Cl. CPC H01L 24/11; H01L 21/56; H01L 25/50; H01L 2224/11622

(57) ABSTRACT

A semiconductor package and a method of manufacturing the same are provided. The method includes stacking plurality of semiconductor chips on a package substrate, covering the package substrate with a photoresist film to surround side and top surfaces of the plurality of semiconductor chips, exposing and developing the photoresist film to form a plurality of openings in the photoresist film over an outer region of the top surface of a corresponding semiconductor chip of the plurality of semiconductor chips, filling the plurality of openings with a conductive material to form a plurality of conductive posts, removing the photoresist film, and forming a molding member surrounding the plurality of semiconductor chips and the plurality of conductive posts, wherein the capping layer comprises a polymer material layer including sulfur.

### CROSS-REFERENCE TO RELATED APPLICATION

This U.S. non-provisional application is based on and claims priority under 35 U.S.C. § 119 to Korean Patent Application No. 10-2024-0110765, filed on Aug. 19, 2024, in the Korean Intellectual Property Office, the disclosure of which is hereby incorporated by reference herein in its entirety.

### BACKGROUND

The inventive concept relates to a semiconductor package and a method of manufacturing the same, and more particularly, to a semiconductor package including conductive posts, and a method of manufacturing the same.

In accordance with the rapid development of the electronics industry and user demands, electronic devices are becoming smaller and lighter. Accordingly, high integration is required for semiconductor devices, which are core components of electronic devices. For a highly integrated semiconductor chip with an increased number of connection terminals for input/output (I/O), semiconductor packages having connection terminals with secured connection reliability are being designed. For example, a semiconductor package, in which a distance between connection patterns and an aspect ratio of the connection patterns are increased to prevent interference between connection terminals, is being developed.

### SUMMARY

The inventive concept relates to a semiconductor package including conductive posts having a high aspect ratio to improve reliability and a method of manufacturing the same.

According to an aspect of the inventive concept, there is provided a method of manufacturing a semiconductor package including stacking a plurality of semiconductor chips on a package substrate such that each semiconductor chip of the plurality of semiconductor chips is shifted in a horizontal direction with respect to each other semiconductor chip of the plurality of semiconductor chips by a predetermined distance and a plurality of upper connection pads formed in an outer region of a top surface of a corresponding semiconductor chip of the plurality of semiconductor chips positioned below are exposed, covering the package substrate with a photoresist film to surround side and top surfaces of each semiconductor chip of the plurality of semiconductor chips, in which the photoresist film includes a photoresist layer and a capping layer arranged on a top surface of the photoresist layer, exposing and developing the photoresist film to form a plurality of openings in an outer region of the photoresist film over the top surface of each semiconductor chip of the plurality of semiconductor chips, filling the plurality of openings with a conductive material to form a plurality of conductive posts, each conductive post of the plurality of conductive posts being connected to a corresponding upper connection pad of the plurality of upper connection pads in the outer region of the top surface of a corresponding semiconductor chip of the plurality of semiconductor chips, removing the photoresist film, and forming a molding member surrounding the plurality of semiconductor chips and the plurality of conductive posts and the capping layer includes a polymer material layer including sulfur.

According to another aspect of the inventive concept, there is provided a method of manufacturing a semiconductor package including stacking a plurality of semiconductor chips on a package substrate such that each semiconductor chip of a plurality of semiconductor chips is shifted in a horizontal direction with respect to each other semiconductor chip of the plurality of semiconductor chips by a predetermined distance and a plurality of upper connection pads formed in an outer region of a top surface of a corresponding semiconductor chip of the plurality of semiconductor chips positioned below are exposed, preparing a photoresist film including a base film, a capping layer, a photoresist layer, and a release film that are sequentially stacked, in which the capping layer includes a polymer material layer including sulfur, removing the release film from the photoresist film, attaching the photoresist film onto the package substrate so that the photoresist layer covers the plurality of semiconductor chips, exposing and developing the photoresist film to form a plurality of openings in the outer region of the photoresist film over the top surface of each semiconductor chip or the plurality of semiconductor chips, filling the plurality of openings with a conductive material to form a plurality of conductive posts, each conductive post of the plurality of conductive posts being connected to a corresponding upper connection pad of the plurality of upper connection pads in the outer region of the top surface of a corresponding semiconductor chip of the plurality of semiconductor chips, removing the photoresist film, forming a molding member surrounding the plurality of semiconductor chips and the plurality of conductive posts, and forming a wiring structure electrically connected to the plurality of conductive posts on the molding member.

According to another aspect of the inventive concept, there is provided a method of manufacturing a semiconductor package including stacking a plurality of semiconductor chips on a package substrate such that each semiconductor chip of the plurality of semiconductor chips is shifted in a horizontal direction with respect to each other semiconductor chip of the plurality of semiconductor chips, by a predetermined distance and a plurality of upper connection pads formed in an outer region of a top surface of a corresponding semiconductor chip of the plurality of semiconductor chips positioned below are exposed, preparing a photoresist film including a base film, a capping layer, a photoresist layer, and a release film that are sequentially stacked, removing the release film from the photoresist film, attaching the photoresist film onto the package substrate so that the photoresist layer covers the plurality of semiconductor chips, exposing and developing the photoresist film to form a plurality of openings in the outer region of the photoresist film over the top surface of each semiconductor chip of the plurality of semiconductor chips, in which a ratio of a height in a vertical direction to a width in a horizontal direction of each opening of the plurality of openings is greater than 8, filling the plurality of openings with a conductive material to form a plurality of conductive posts, each conductive post of the plurality of conductive posts being connected to a corresponding upper connection pad of the plurality of upper connection pads in the outer region of the top surface of a corresponding semiconductor chip of the plurality of semiconductor chips, removing the photoresist film, forming a molding member surrounding the plurality of semiconductor chips and the plurality of conductive posts, and forming a wiring structure electrically connected to the plurality of conductive posts on the molding member. The capping layer includes a polymer material layer including sulfur, the capping layer is formed by a radical reaction between sulfur molecules and allyl monomers, the capping layer has a refractive index in a range of 1.5 to 2.0, and the capping layer has a thickness in a range of 5 nanometers to 5 micrometers.

According to another aspect of the inventive concept, there are provided semiconductor packages manufactured by each of the present methods.

### BRIEF DESCRIPTION OF THE DRAWINGS

Embodiments will be more clearly understood from the following detailed description taken in conjunction with the accompanying drawings in which:

FIG. 1 is a cross-sectional view illustrating a photoresist (PR) film according to embodiments;

FIG. 2 is a cross-sectional view illustrating a photoresist film according to embodiments;

FIG. 3 is a flowchart illustrating a method of manufacturing a photoresist film according to embodiments;

FIG. 4 is a cross-sectional view illustrating a semiconductor package according to embodiments;

FIG. 5 is a flowchart illustrating a method of manufacturing a semiconductor package according to embodiments;

FIGS. 6 to 17 are cross-sectional views illustrating, in a process order, a method of manufacturing a semiconductor package according to embodiments;

FIG. 18 is a flowchart illustrating a method of manufacturing a semiconductor package according to embodiments; and

FIGS. 19 to 21 are cross-sectional views illustrating a method of manufacturing a semiconductor package according to embodiments.

### DETAILED DESCRIPTION OF THE EMBODIMENTS

Hereinafter, embodiments of the inventive concept will be described in detail with reference to the accompanying drawings. The invention may, however, be embodied in many different forms and should not be construed as limited to the example embodiments set forth herein.

Throughout the specification, when a component is described as “including” a particular element or group of thereof, it is to be understood that the component is formed of only the element or the group of elements, or the element or group of elements may be combined with additional elements to form the component, unless the context indicates otherwise.

Items described in the singular herein may be provided in plural, as can be seen, for example, in the drawings. Thus, the description of a single item that is provided in plural should be understood to be applicable to the remaining plurality of items unless context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Spatially relative terms, such as “below,” “lower,” “upper,”, “top”, “bottom,” and the like, may be used herein for ease of description to describe positional relationships, such as illustrated in the figures, for example. It will be understood that the spatially relative terms encompass different orientations of the device in addition to the orientation depicted in the figures.

The thickness of a layer may refer to the dimension in the direction perpendicular to the surface of the layer.

As used herein, the words “surround” and “surrounding” and “surrounded” are intended to mean that an element is outside the other element. The elements may be touching or not. The surrounding element may or may not completely surround an inner element.

According to an aspect of the inventive concept, there is provided a photoresist film that includes a base film, a first capping layer over the base film, and a photoresist layer over the first capping layer, in which the first capping layer comprises a polymer material including sulfur. and the first capping layer includes a polymer material having a greater refractive index than a refractive index of the photoresist layer.

In some embodiments, the polymer material of the first capping layer may have a greater refractive index than a refractive index of the base film.

In some embodiments, the first capping layer may have a refractive index of 1.5 to 2.

In some embodiments, the photoresist film may further include a release film over the photoresist layer.

In some embodiments, the first capping layer may have a thickness of 5 nanometers to 5 micrometers.

In some embodiments, the photoresist layer may have a thickness of 5 micrometers to 500 micrometers.

In some embodiments, the base film may have a thickness of 5 micrometers to 100 micrometers.

In some embodiments, the first capping layer may cover an entire top surface of the base film.

In some embodiments, the base film may include at least one material selected from the group consisting of polyolefin (PO), polyethylene terephthalate (PET), polyether ether ketone (PEEK), polymethyl methacrylate (PMA), and polyimide (PI).

In some embodiments, the photoresist film may further include a second capping layer over the photoresist layer.

In some embodiments, the second capping layer may cover an entire top surface of the photoresist layer.

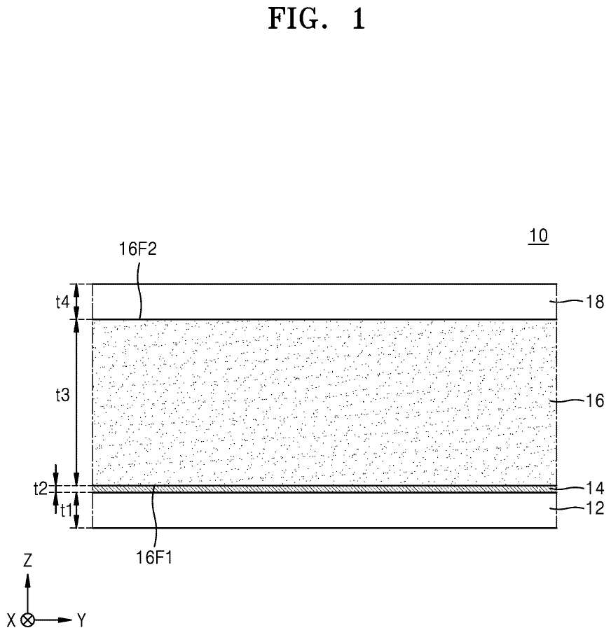

FIG. 1 is a cross-sectional view illustrating a photoresist film 10 according to embodiments.

The photoresist film 10 described with reference to FIG. 1 may be a film that may be used in a method of manufacturing a semiconductor package according to embodiments. For example, the photoresist film 10 described with reference to FIG. 1 may include or be a film or film-type photoresist material layer that may be used to form a conductive post having a high aspect ratio and may be attached onto a semiconductor wafer by lamination.

Referring to FIG. 1, the photoresist film 10 may include a base film 12, a capping layer 14, a photoresist layer 16, and a release film 18.

In embodiments, the base film 12 may include at least one of polyolefin (PO), polyethylene terephthalate (PET), polyether ether ketone (PEEK), polymethyl methacrylate (PMA), and/or polyimide (PI).

In embodiments, the base film 12 may have a first thickness t1 in a range of 5 micrometers to 100 micrometers, or 10 micrometers to 90 micrometers, or 20 micrometers to 80 micrometers.

In embodiments, the capping layer 14 may include or be a material layer having a high refractive index. In embodiments, the capping layer 14 may be a polymer material including sulfur. In embodiments, the capping layer 14 may be a material formed by a radical reaction between sulfur and an allyl monomer. In embodiments, the capping layer 14 may be formed on the base film 12 using a chemical vapor deposition (CVD) method by a radical reaction between S₈ molecules and allyl monomers. The allyl monomer may include or be an aliphatic, aromatic, and/or siloxane group.

In embodiments, the capping layer 14 may include or be a material having a higher refractive index than a photoresist material. In embodiments, the capping layer 14 may include or be a material having a higher refractive index than the base film 12. In embodiments, the capping layer 14 may have a refractive index greater than 1.5 or 1.7. In some embodiments, the capping layer 14 may have a refractive index greater than 1.9. In some embodiments, the capping layer 14 formed by a radical reaction between sulfur and an allyl monomer may have a refractive index of 1.95. In some embodiments, the capping layer 14 may have a refractive index in a range of 1.5 to 2.0, or 1.7 to 1.98.

In embodiments, the capping layer 14 may be formed to cover an entire top surface of the base film 12. In embodiments, the capping layer 14 may have a second thickness t2 in a range of 5 nanometers to 5 micrometers, or 50 nanometers to 4 micrometers, or 100 nanometers to 3 micrometers.

In embodiments, the photoresist layer 16 may include or be a negative photoresist material. Here, the term “negative photoresist material” may refer to a photoresist material used in a negative tone development method. For example, in the negative tone development method, an exposed portion (for example, a portion irradiated with light of a critical light amount or more) of a photoresist material layer may remain and an unexposed portion (for example, a portion that is not irradiated with light of a critical light amount or more) of the photoresist material layer may be removed by a solvent. In embodiments, the photoresist layer 16 may include resin, a photosensitizer, and a solvent, for example, resin may include a (meth)acrylate-based polymer. The (meth)acrylate-based polymer may be an aliphatic (meth)acrylate-based polymer.

In embodiments, the photoresist layer 16 may include or be a positive photoresist material. Here, the term “positive photoresist material” may refer to a photoresist material used in a positive tone development method. For example, in a positive tone development method, an unexposed portion (for example, a portion that is not irradiated with light of a critical light amount or more) of a photoresist material layer may remain and an exposed portion (for example, a portion irradiated with light of a critical light amount or more) of the photoresist material layer may be removed by a solvent. In embodiments, the photoresist layer 16 may include resin, a photosensitizer, and a solvent. In embodiments, the photosensitizer may include or be a photoactive compound such as diazonaphthaquinones (DNQ).

In embodiments, the photoresist layer 16 may include a chemically amplified resist (CAR) material. In embodiments, a chemically amplified photoresist material may include photosensitive resin with an acid-labile group, potential acid, and a solvent. In addition, the photosensitive resin may be replaced with various acid-labile protecting groups.

In embodiments, the photoresist layer 16 may have a third thickness t3 in a range of 5 micrometers to 500 micrometers, or 50 micrometers to 450 micrometers or 100 micrometers to 400 micrometers.

In embodiments, the release film 18 may include at least one of PO, PET, PEEK, PMA, and/or PI.

In embodiments, the release film 18 may have a fourth thickness t4 in a range of 5 micrometers to 100 micrometers, or 10 micrometers to 90 micrometers, or 20 micrometers to 80 micrometers.

In embodiments, the photoresist layer 16 may include a first surface 16F1 and a second surface 16F2, the first surface 16F1 of the photoresist layer 16 may contact the capping layer 14, and the second surface 16F2 of the photoresist layer 16 may contact the release film 18.

The photoresist film 10 according to embodiments may be attached and used by a lamination method in a semiconductor package manufacturing process. In embodiments, the photoresist film 10 may be referred to as a dry photoresist film in that the photoresist film 10 is manufactured in the form of a film with a multi-layer configuration including a photoresist layer and is provided for use in the semiconductor package manufacturing process.

In embodiments, when the photoresist film 10 is used in the semiconductor package manufacturing process, the second surface 16F2 of the photoresist layer 16 may be exposed with the release film 18 removed, and the second surface 16F2 of the photoresist layer 16 may be attached to an object (for example, a lower layer or a material layer on a semiconductor wafer). Thereafter, the base film 12 may be removed or separated from the photoresist layer 16 and the capping layer 14, and the entire first surface 16F1 of the photoresist layer 16 may be covered with the capping layer 14. Thereafter, an exposure process of a photolithography process may be performed on the photoresist layer 16 and the capping layer 14.

In embodiments, as the capping layer 14 on the photoresist layer 16 has a higher refractive index than a photoresist material, rectilinearity of light irradiated in the exposure process may be improved so that an opening having a relatively high aspect ratio may be formed in the semiconductor package manufacturing process.

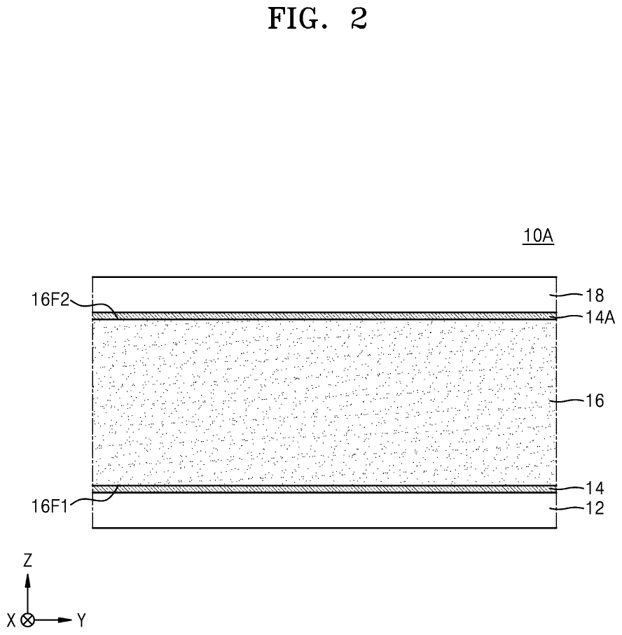

FIG. 2 is a cross-sectional view illustrating a photoresist film 10A according to embodiments.

Referring to FIG. 2, the photoresist film 10A may include a base film 12, a first capping layer 14, a photoresist layer 16, a second capping layer 14A, and a release film 18. In embodiments, the first surface 16F1 of the photoresist layer 16 may contact the first capping layer 14, and the second surface 16F2 of the photoresist layer 16 may contact the second capping layer 14A.

In embodiments, the second capping layer 14A may include a material layer having a high refractive index. In embodiments, the second capping layer 14A may include a polymer material including sulfur. In embodiments, the second capping layer 14A may include a material formed by a radical reaction between sulfur and an allyl monomer. In embodiments, the second capping layer 14A may be formed on the photoresist layer 16 using a CVD method by a radical reaction between Ss molecules and allyl monomers. The allyl monomer may include an aliphatic, aromatic, or siloxane group.

In embodiments, the second capping layer 14A may include a material having a higher refractive index than a photoresist material. In embodiments, the second capping layer 14A may include a material having a higher refractive index than the base film 12. In embodiments, the second capping layer 14A may have a refractive index greater than 1.5 or 1.7. In some embodiments, the second capping layer 14A may have a refractive index greater than 1.9. In some embodiments, the second capping layer 14A formed by a radical reaction between sulfur and an allyl monomer may have a refractive index of 1.95. In some embodiments, the second capping layer 14A may have a refractive index in a range of 1.5 to 2.0, or 1.7 to 1.98.

In embodiments, the second capping layer 14A may be formed to cover the entire second surface 16F2 of the photoresist layer 16. In embodiments, the second capping layer 14A may have a thickness in a range of 5 nanometers to 5 micrometers, or 50 nanometers to 4 micrometers, or 100 nanometers to 3 micrometers.

The photoresist film 10A according to embodiments may be attached and used by a lamination method in a semiconductor package manufacturing process. In embodiments, as each of the first capping layer 14 and the second capping layer 14A has a higher refractive index than a photoresist material, rectilinearity of light irradiated in the exposure process may be improved so that an opening having a relatively high aspect ratio may be formed in the semiconductor package manufacturing process.

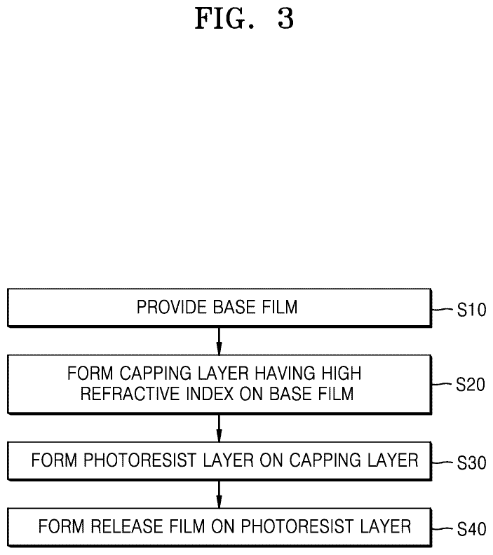

FIG. 3 is a flowchart illustrating a method of manufacturing a photoresist film according to embodiments.

Referring to FIG. 3 together with FIG. 1, the base film 12 may be provided in operation S10.

In embodiments, the base film 12 may include at least one of PO, PET, PEEK, PMA, and/or PI. In embodiments, the base film 12 may have a first thickness t1 in a range of 5 micrometers to 100 micrometers, or 10 micrometers to 90 micrometers, or 20 micrometers to 80 micrometers.

Thereafter, the capping layer 14 having a high refractive index may be formed on the base film 12 in operation S20.

In embodiments, the capping layer 14 may include a polymer material including sulfur. In embodiments, the capping layer 14 may include a material formed by a radical reaction between sulfur and an allyl monomer. In embodiments, the capping layer 14 may be formed on the base film 12 by a radical reaction between Ss molecules and allyl monomers. The allyl monomer may include an aliphatic, aromatic, or siloxane group.

In embodiments, the capping layer 14 may be formed by a CVD process. In embodiments, S& molecules and allyl monomers may be provided into a reaction chamber as precursors. In the CVD process, heat may be supplied to the reaction chamber using a heater or a hot filament to generate a radical reaction of Ss molecules. Ring-shaped Ss molecules may be evaporated by a heater or a hot filament to generate sulfur radicals from the Ss molecules, and a polymer material including sulfur may be generated through a polymerization reaction between an allyl monomer and a sulfur radical.

In embodiments, the capping layer 14 may include a material having a higher refractive index than a photoresist material. In embodiments, the capping layer 14 may have a refractive index greater than 1.5, 1.7, or 1.9. In some embodiments, the capping layer 14 formed by a radical reaction between sulfur and an allyl monomer may have a refractive index of 1.95. In some embodiments, the capping layer 14 may have a refractive index in a range of 1.5 to 2.0, or 1.7 to 1.98.

In embodiments, the capping layer 14 may be formed to a second thickness t2 in a range of 5 nanometers to 5 micrometers, or 50 nanometers to 4 micrometers, or 100 nanometers to 3 micrometers.

Thereafter, the photoresist layer 16 may be formed on the capping layer 14 in operation S30.

In embodiments, the photoresist layer 16 may include a negative photoresist material. In embodiments, the photoresist layer 16 may include resin, a photosensitizer, and a solvent, for example, resin may include a (meth)acrylate-based polymer. The (meth)acrylate-based polymer may include an aliphatic (meth)acrylate-based polymer.

In embodiments, the photoresist layer 16 may include a positive photoresist material. In embodiments, the photoresist layer 16 may include resin, a photosensitizer, and a solvent. In embodiments, the photosensitizer may include a photoactive compound such as diazonaphthaquinones (DNQ).

In embodiments, the photoresist layer 16 may include a CAR material. In embodiments, a chemically amplified photoresist material may include photosensitive resin with an acid-labile group, potential acid, and a solvent. In addition, the photosensitive resin may be replaced with various acid-labile protecting groups.

In embodiments, the photoresist layer 16 may be formed on a top surface of the capping layer 14 by spin coating. In embodiments, the photoresist layer 16 may be formed to a third thickness t3 in a range of 5 micrometers to 500 micrometers, or 50 micrometers to 450 micrometers or 100 micrometers to 400 micrometers.

Thereafter, the release film 18 may be formed on the photoresist layer 16 in operation S40.

In embodiments, the release film 18 may include at least one of PO, PET, PEEK, PMA, and/or PI. In embodiments, the release film 18 may have a fourth thickness t4 in a range of 5 micrometers to 100 micrometers, or 10 micrometers to 90 micrometers, or 20 micrometers to 80 micrometers.

In embodiments, the photoresist film 10 may be used in the semiconductor package manufacturing process. For example, the photoresist film 10 may be attached onto a semiconductor wafer by lamination and may be used in an exposure process for forming an opening with a high aspect ratio.

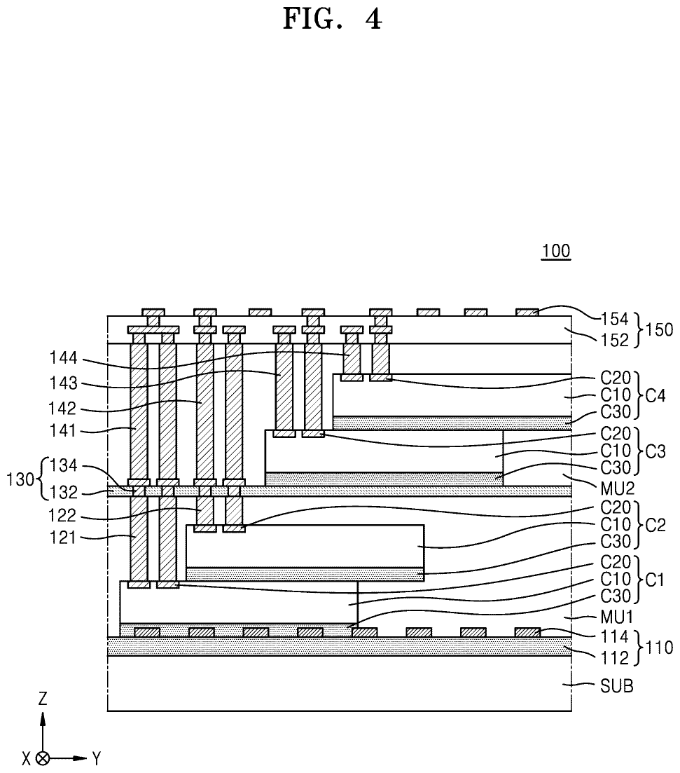

FIG. 4 is a cross-sectional view illustrating a semiconductor package 100 according to embodiments.

Referring to FIG. 4, the semiconductor package 100 may include a package substrate SUB, first to fourth semiconductor chips C1, C2, C3, and C4, a plurality of first and second lower conductive posts 121 and 122, a plurality of first to fourth upper conductive posts 141, 142, 143, and 144, first and second molding members MU1 and MU2, and first to third wiring structures 110, 130, and 150.

The semiconductor package 100 may include low power double data rate (LPDDR) memory consuming low power.

The package substrate SUB may function as a base substrate, a wiring substrate, and/or an external terminal connection substrate. The package substrate SUB may be formed based on a semiconductor substrate, a printed circuit board (PCB), a ceramic substrate, or a glass substrate. In some embodiments, the package substrate SUB may be an interposer. In other embodiments, the package substrate SUB may be omitted.

In some embodiments, each of the first wiring structure 110, the second wiring structure 130, and the third wiring structure 150 may be formed by a corresponding redistribution process. Therefore, the first wiring structure 110, the second wiring structure 130, and the third wiring structure 150 may be referred to as a lower redistribution structure, an intermediate redistribution structure, and an upper redistribution structure.

The first wiring structure 110 may be formed on the package substrate SUB. The first wiring structure 110 may include a first insulating layer 112 and a plurality of first conductive patterns 114. The first insulating layer 112 may surround the plurality of first conductive patterns 114 or may be arranged under the plurality of first conductive patterns 114. In some embodiments, the first wiring structure 110 may include a plurality of stacked first insulating layers 112.

The plurality of first conductive patterns 114 may include, for example, a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Rc), beryllium (Be), gallium (Ga), or ruthenium (Ru), and/or an alloy of the metal.

A first semiconductor chip C1 may be mounted on the first wiring structure 110. The first semiconductor chip C1 may include a semiconductor substrate C10 having an active surface and an inactive surface facing each other. A first surface and a second surface of the first semiconductor chip C1 may face each other, and the first surface of the first semiconductor chip C1 means the active surface of the semiconductor substrate C10. Therefore, illustration distinguishing the active surface of the semiconductor substrate C10 from the first surface of the first semiconductor chip C1 is omitted.

The first semiconductor chip C1 may be a semiconductor device (not shown) formed on the active surface of the semiconductor substrate C10 and a plurality of upper connection pads C20 formed on the first surface of the first semiconductor chip C1. In some embodiments, the first semiconductor chip C1 has an arrangement in which the second surface faces the first wiring structure 110, and may be mounted on a top surface of the first wiring structure 110 through a die attach film C30.

The semiconductor substrate C10 may include, for example, a semiconductor material such as silicon (Si) and/or germanium (Ge). Alternatively, the semiconductor substrate C10 may include a compound semiconductor material such as silicon carbide (SiC), gallium arsenide (GaAs), indium arsenide (InAs), and/or indium phosphide (InP). The semiconductor substrate C10 may include a well doped with impurities, which is a conductive region. The semiconductor substrate C10 may have various device isolation structures such as a shallow trench isolation (STI) structure.

Although not shown, a semiconductor device including a plurality of various types of individual devices may be formed on the active surface of the semiconductor substrate C10. The semiconductor device may be electrically connected to the conductive region of the semiconductor substrate C10. The semiconductor device may further include a conductive wire and/or a conductive plug electrically connecting the plurality of individual devices to the conductive region of the semiconductor substrate C10.

As used herein, components described as being “electrically connected” are configured such that an electrical signal can be transferred from one component to the other (although such electrical signal may be attenuated in strength as it is transferred and may be selectively transferred).

The plurality of upper connection pads C20 may be arranged in an outer region on the first surface of the first semiconductor chip C1. As described herein, the plurality of upper connection pads C20 may be arranged in regions exposed from the second to fourth semiconductor chips C2, C3, and C4 stacked on the first semiconductor chip C1. Accordingly, the plurality of first lower conductive posts 121 may contact the plurality of upper connection pads C20 of the first semiconductor chip C1. The plurality of first lower conductive posts 121 may connect the first semiconductor chip C1 to the outside.

The die attach film C30 may be divided into inorganic adhesive and polymer adhesive. In the polymer adhesive, the polymer may be divided into thermosetting resin and thermoplastic resin and the thermosetting resin has a three-dimensional network configuration after a monomer is heat-molded and does not soften even when reheated. In contrast, the thermoplastic resin exhibiting plasticity by heating has a linear polymer structure. In addition, there is also a hybrid polymer made by mixing these two ingredients.

The first semiconductor chip C1 may include a memory device. For example, the memory device may include a non-volatile memory device such as flash memory, phase-change random access memory (PRAM), magnetoresistive random access memory (MRAM), ferroelectric random access memory (FeRAM), and/or resistive random access memory (RRAM). In some embodiments, the memory device may include a volatile memory device such as dynamic random access memory (DRAM) and/or static random access memory (SRAM).

The second semiconductor chip C2 may be stacked and mounted on the first semiconductor chip C1 in a vertical direction (Z direction) to be shifted in a first horizontal direction (X direction) by a first predetermined distance so that the plurality of upper connection pads C20 formed in the outer region of the top surface of the first semiconductor chip C1 are exposed.

The second semiconductor chip C2 may be the same or substantially the same as the first semiconductor chip C1. Therefore, a difference from the first semiconductor chip C1 described herein will be mainly described.

In the second semiconductor chip C2, the plurality of upper connection pads C20 may be arranged in an outer region on a first surface of the second semiconductor chip C2. As will be described later, the plurality of upper connection pads C20 may be arranged in regions exposed from the third and fourth semiconductor chips C3 and C4 stacked on the second semiconductor chip C2. Accordingly, the plurality of second lower conductive posts 122 may contact the plurality of upper connection pads C20 of the second semiconductor chip C2. The plurality of second lower conductive posts 122 may connect the second semiconductor chip C2 to the outside.

The first molding member MU1 may surround the first semiconductor chip C1 and the second semiconductor chip C2 on the top surface of the first wiring structure 110. The first molding member MU1 may fill a space between the first wiring structure 110 and the second wiring structure 130. The first molding member MU1 may include, for example, an epoxy mold compound (EMC). In addition, the first molding member MU1 may further include a filler.

The first molding member MU1 may surround the plurality of first and second lower conductive posts 121 and 122. For example, the plurality of first and second lower conductive posts 121 and 122 may electrically connect the first wiring structure 110 to the second wiring structure 130 through the first molding member MU1.

The second wiring structure 130 may be arranged on the first molding member MU1. The second wiring structure 130 may include a second insulating layer 132 and a plurality of second conductive patterns 134. The second insulating layer 132 may be arranged to surround the plurality of second conductive patterns 134. In some embodiments, the second wiring structure 130 may include a plurality of stacked second insulating layers 132.

The plurality of second conductive patterns 134 may be connected to the plurality of first and second lower conductive posts 121 and 122 arranged under the second wiring structure 130. The plurality of second conductive patterns 134 may be connected to the plurality of first and second upper conductive posts 141 and 142 arranged on the second wiring structure 130. For example, the first semiconductor chip C1 may be connected to the outside through the plurality of first lower conductive posts 121 and the plurality of first upper conductive posts 141. In addition, the second semiconductor chip C2 may be connected to the outside through the plurality of second lower conductive posts 122 and the plurality of second upper conductive posts 142.

The third semiconductor chip C3 may be stacked and mounted on the second wiring structure 130 in the vertical direction (Z direction) to be shifted from the second semiconductor chip C2 in the first horizontal direction (X direction) by a second predetermined distance so that the plurality of upper connection pads C20 formed in the outer region of the top surface of the second semiconductor chip C2 are exposed.

The third semiconductor chip C3 may be the same or substantially the same as the first semiconductor chip C1. Therefore, a difference from the first semiconductor chip C1 described herein will be mainly described.

In the third semiconductor chip C3, the plurality of upper connection pads C20 may be arranged in an outer region on a first surface of the third semiconductor chip C3. As will be described later, the plurality of upper connection pads C20 may be arranged in a region exposed from the fourth semiconductor chip C4 stacked on the third semiconductor chip C3. Accordingly, the plurality of third upper conductive posts 143 may contact the plurality of upper connection pads C20 of the third semiconductor chip C3. The plurality of third upper conductive posts 143 may connect the third semiconductor chip C3 to the outside.

The fourth semiconductor chip C4 may be stacked and mounted on the third semiconductor chip C3 in the vertical direction (Z direction) to be shifted in the first horizontal direction (X direction) by a third predetermined distance so that the plurality of upper connection pads C20 formed in the outer region of the top surface of the third semiconductor chip C3 are exposed.

The fourth semiconductor chip C4 may be the same or substantially the same as the first semiconductor chip C1. Therefore, a difference from the first semiconductor chip C1 described herein will be mainly described.

In the fourth semiconductor chip C4, the plurality of upper connection pads C20 may be arranged in an outer region on a first surface of the fourth semiconductor chip C4. The plurality of fourth upper conductive posts 144 may contact the plurality of upper connection pads C20 of the fourth semiconductor chip C4. The plurality of fourth upper conductive posts 144 may connect the fourth semiconductor chip C4 to the outside.

The second molding member MU2 may surround the third semiconductor chip C3 and the fourth semiconductor chip C4 on a top surface of the second wiring structure 130. The second molding member MU2 may fill a space between the second wiring structure 130 and the third wiring structure 150. The second molding member MU2 may include the same or substantially the same material as the first molding member MU1.

The second molding member MU2 may surround the plurality of first to fourth upper conductive posts 141, 142, 143, and 144. For example, the plurality of first to fourth upper conductive posts 141, 142, 143, and 144 may electrically connect the second wiring structure 130 to the third wiring structure 150 through the second molding member MU2.

The third wiring structure 150 may be formed on the second molding member MU2. The third wiring structure 150 may include a third insulating layer 152 and a plurality of third conductive patterns 154. The third insulating layer 152 may be arranged to surround the plurality of third conductive patterns 154. In some embodiments, the third wiring structure 150 may include a plurality of stacked third insulating layers 152.

The plurality of third conductive patterns 154 may be connected to the plurality of first to fourth upper conductive posts 141, 142, 143, and 144 arranged under the third wiring structure 150. For example, the first semiconductor chip C1 may be connected to the outside through the plurality of first lower conductive posts 121 and the plurality of first upper conductive posts 141. In addition, the second semiconductor chip C2 may be connected to the outside through the plurality of second lower conductive posts 122 and the plurality of second upper conductive posts 142. The third semiconductor chip C3 may be connected to the outside through the plurality of third upper conductive posts 143. In addition, the fourth semiconductor chip C4 may be connected to the outside through the plurality of fourth upper conductive posts 144.

A length of each first and second upper conductive post of the plurality of first and second upper conductive posts 141 and 142 in the vertical direction (Z direction) may be 100 micrometers to 1,000 micrometers, or 200 micrometers to 900 micrometers. In addition, an aspect ratio, a ratio of a height to a horizontal width of each first and second upper conductive post of the plurality of first and second upper conductive posts 141 and 142 may be greater than 8, or greater than 9, or greater than 10.

In general, an exposure process and a development process using photoresist are used to form a conductive post. As a height of a conductive post increases, a thickness of photoresist also needs to increase, but there is a problem that resolution or light transmittance of photoresist is significantly reduced when the thickness is greater than a certain thickness. Therefore, two exposure processes, two development processes, and two plating processes are used to form a conductive post of an increased height, but there is a problem of significantly increasing the number of steps in the manufacturing process.

The semiconductor package 100 according to embodiments may use a photoresist film including a high refractive index capping layer described with reference to FIGS. 1 and 2, or a photoresist film or a photoresist layer including a high refractive index capping layer according to a method of manufacturing a semiconductor package to be described herein to form a conductive post having a high aspect ratio by one-time exposure, development, and plating processes. Therefore, reliability of the semiconductor package 100 may be increased and manufacturing cost of the semiconductor package 100 may be reduced.

In embodiments, the semiconductor package according to the inventive concept may include semiconductor packages with various configurations in addition to those described with reference to FIG. 4. In embodiments, a semiconductor package according to the inventive concept may include various types of semiconductor packages including conductive posts having a relatively high aspect ratio. In embodiments, a semiconductor package according to the inventive concept may include a fan-out package including conductive posts having a relatively high aspect ratio. In embodiments, a semiconductor package according to the inventive concept may include a 2.5D package including conductive posts having a relatively high aspect ratio.

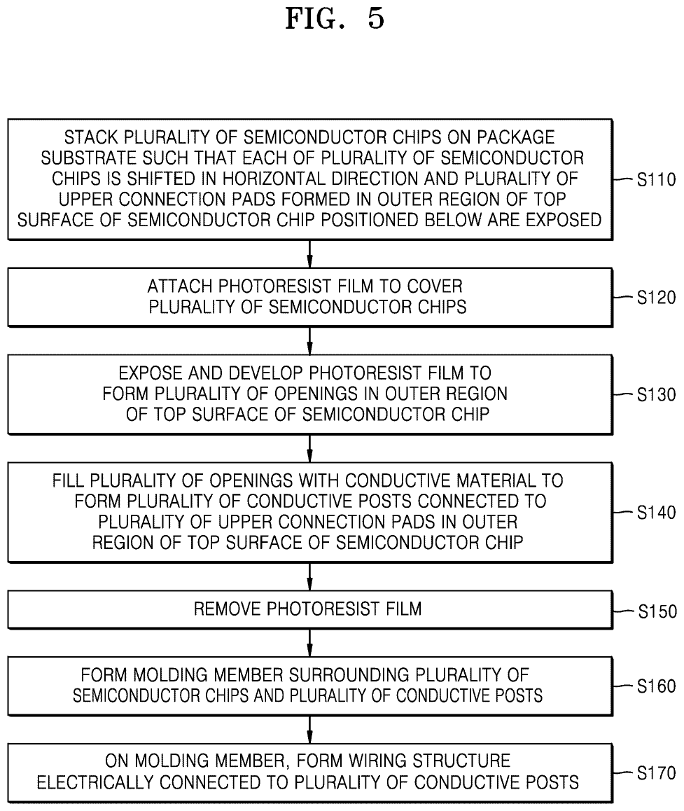

FIG. 5 is a flowchart illustrating a method of manufacturing a semiconductor package according to embodiments.

Referring to FIG. 5, the method of manufacturing a semiconductor package according to embodiments may include operation S110 of stacking a plurality of semiconductor chips on a package substrate such that each semiconductor chip of the plurality of semiconductor chips is shifted in a horizontal direction with respect to each other semiconductor chip of the plurality of semiconductor chips, by a predetermined distance and a plurality of upper connection pads formed in an outer region of a top surface of a semiconductor chip positioned below are exposed, operation S120 of attaching a photoresist film to cover the plurality of semiconductor chips, operation $130 of exposing and developing the photoresist film to form a plurality of openings in the outer region of the photoresist film over the top surface of the semiconductor chip, operation S140 of filling the plurality of openings with a conductive material to form a plurality of conductive posts, each conductive post being connected to a corresponding upper connection pad from the plurality of upper connection pads in the outer region of the top surface of a corresponding semiconductor chip, operation S150 of removing the photoresist film, operation S160 of forming a molding member surrounding the plurality of semiconductor chips and the plurality of conductive posts, and operation S170 of forming a wiring structure electrically connected to the plurality of conductive posts on the molding member.

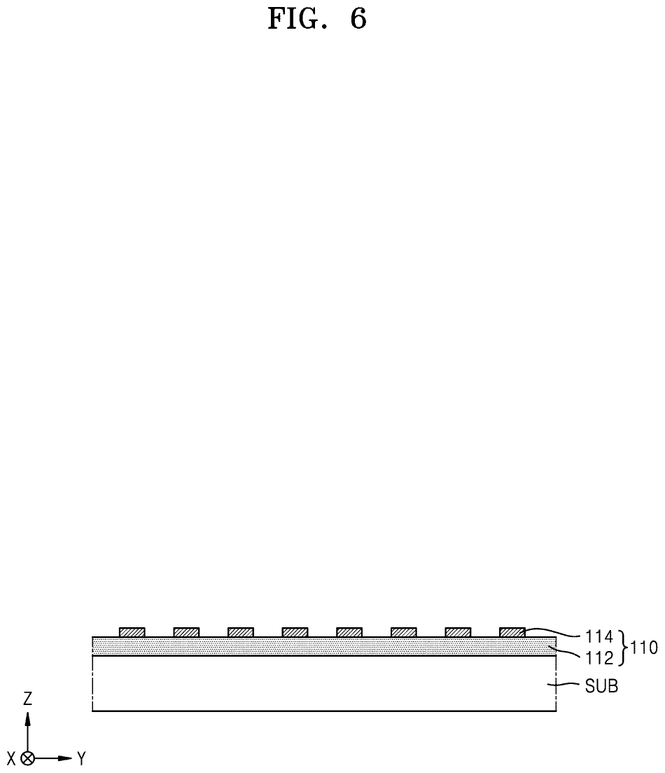

Technical features of each of the herein-described operations S110 to S170 will be described in detail with reference to FIGS. 6 to 17 described herein.

FIGS. 6 to 17 are cross-sectional views illustrating a method of manufacturing a semiconductor package according to embodiments in a process order.

Referring to FIG. 6, the first wiring structure 110 including the first insulating layer 112 and the plurality of first conductive patterns 114 is formed on the package substrate SUB.

The package substrate SUB may be formed based on a semiconductor substrate, a printed circuit board (PCB), a ceramic substrate, or a glass substrate. In some embodiments, a release film may be attached onto the package substrate SUB and the first wiring structure 110 may be formed.

In some embodiments, the plurality of first conductive patterns 114 may be a conductive layer arranged on a top surface of the first insulating layer 112.

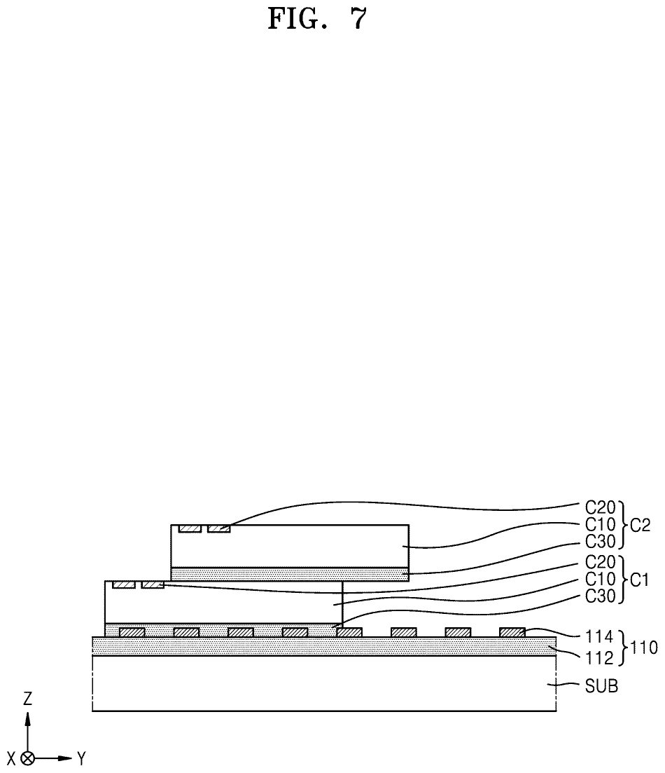

Referring to FIG. 7, the first and second semiconductor chips C1 and C2 are sequentially mounted on the first wiring structure 110.

Each of the first and second semiconductor chips C1 and C2 may be shifted by a predetermined distance in the first horizontal direction (X direction) on the package substrate SUB, and may be stacked so that the plurality of upper connection pads C20 formed on part of a top surface of a semiconductor chip (for example, the first semiconductor chip) positioned below are exposed. The mounting process may be performed by using the die attach film C30 attached to a bottom surface of each of the first and second semiconductor chips C1 and C2.

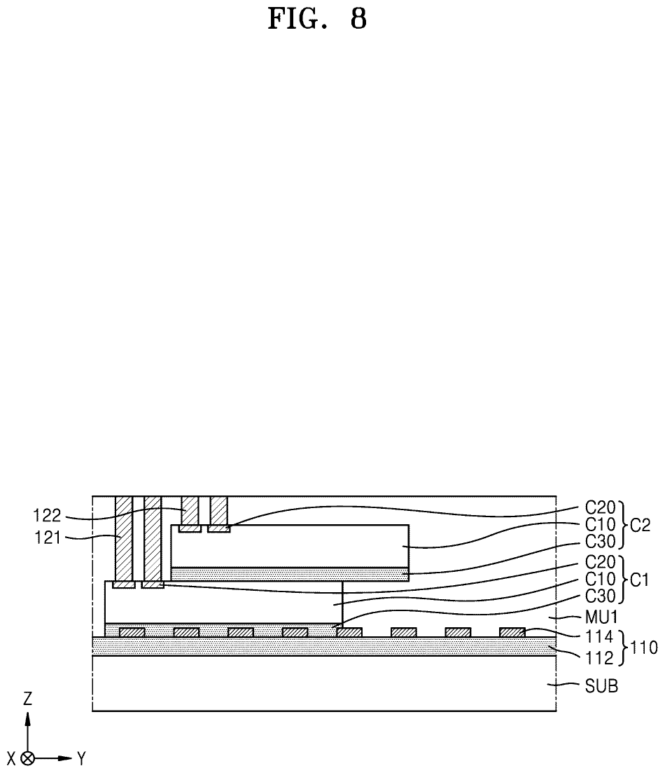

Referring to FIG. 8, the plurality of first and second lower conductive posts 121 and 122 are formed on the first and second semiconductor chips C1 and C2.

The plurality of first and second lower conductive posts 121 and 122 may be formed by forming a photo-mask through an exposure process and a development process and then manufacturing conductive posts through a plating process.

Next, the first molding member MU1 covering the package substrate SUB and the first and second semiconductor chips C1 and C2 and exposing top surfaces of the plurality of first and second lower conductive posts 121 and 122 may be formed.

The first molding member MU1 is formed on a top surface of the package substrate SUB to surround the first and second semiconductor chips C1 and C2 and the plurality of first and second lower conductive posts 121 and 122 and to protect the first and second semiconductor chips C1 and C2 and the plurality of first and second lower conductive posts 121 and 122 from an external environment.

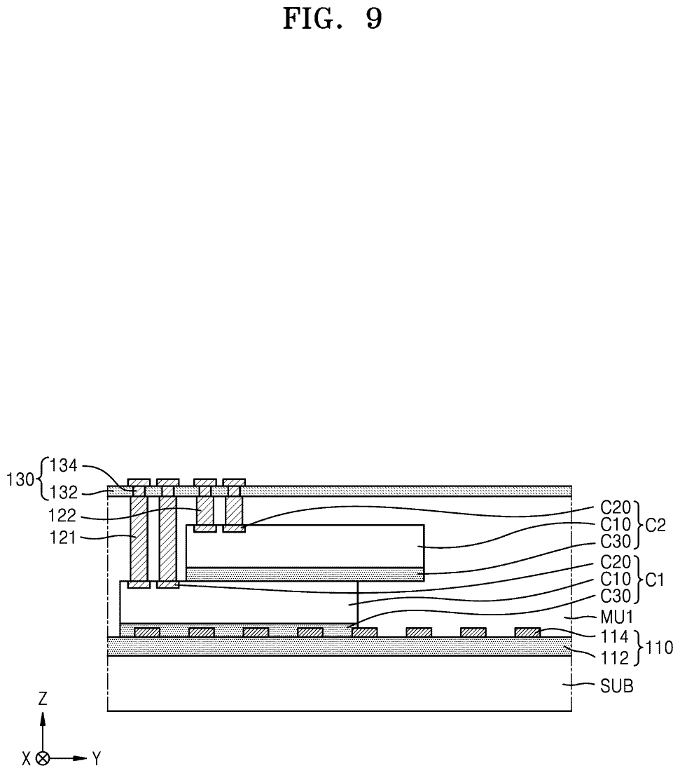

Referring to FIG. 9, the second wiring structure 130 including the second insulating layer 132 and the plurality of second conductive patterns 134 is formed on the first molding member MU1 and the plurality of first and second lower conductive posts 121 and 122.

In the second wiring structure 130, the second insulating layer 132 may be formed to surround the plurality of second conductive patterns 134. In some embodiments, the second wiring structure 130 may include a plurality of stacked second insulating layers 132.

The plurality of second conductive patterns 134 may be connected to the plurality of first and second lower conductive posts 121 and 122 arranged under the second wiring structure 130.

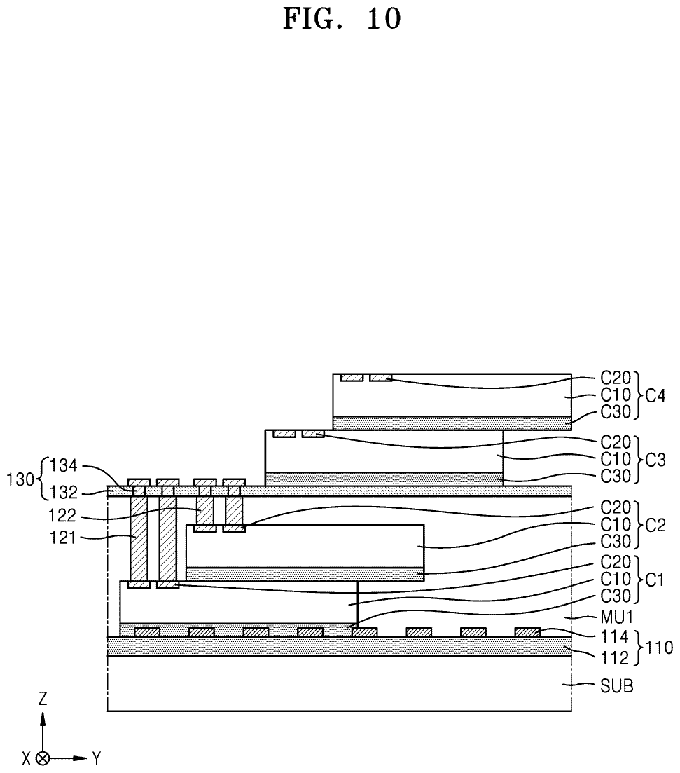

Referring to FIG. 10, the third and fourth semiconductor chips C3 and C4 are sequentially mounted on the second wiring structure 130.

Each of the third and fourth semiconductor chips C3 and C4 may be shifted by a predetermined distance in the first horizontal direction (X direction) on the second wiring structure 130 and may be stacked so that the plurality of upper connection pads C20 formed on part of a top surface of a semiconductor chip (for example, the third semiconductor chip) positioned below and the plurality of second conductive patterns 134 connected to the plurality of first and second lower conductive posts 121 and 122 are exposed. The mounting process may be performed by using the die attach film C30 attached to a bottom surface of each of the third and fourth semiconductor chips C3 and C4.

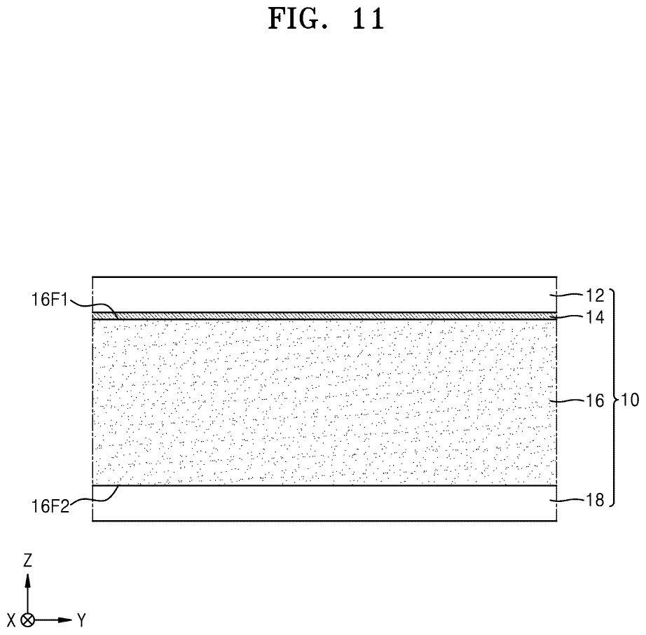

Referring to FIG. 11, to use as a photo-mask, the photoresist film 10 is prepared.

The photoresist film 10 may include a base film 12, a capping layer 14, a photoresist layer 16, and a release film 18. The photoresist film 10 may have features that are the same as, or substantially the same as, those described with reference to FIG. 1. The photoresist film 10 may be formed by the manufacturing method described with reference to FIG. 3.

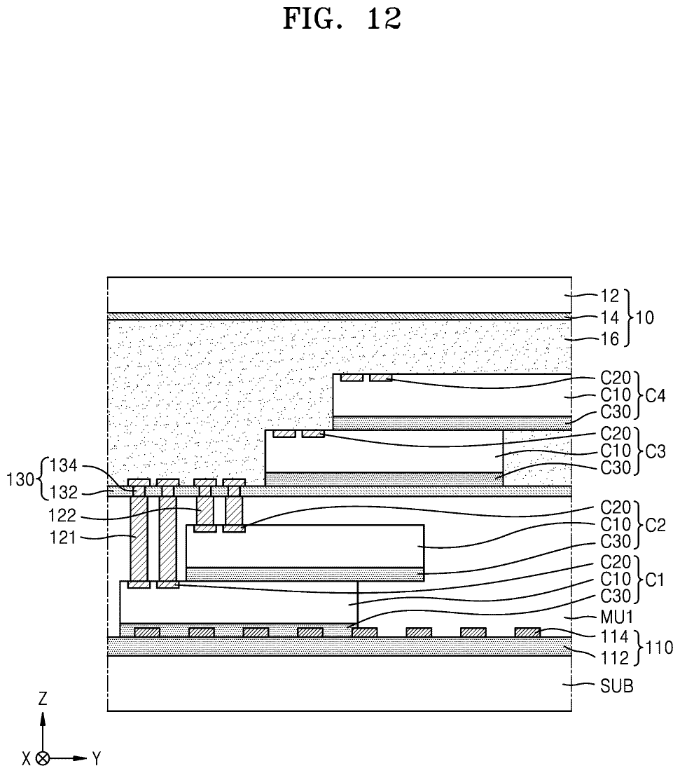

Referring to FIG. 12, the release film 18 is removed from the photoresist film 10, and the second surface 16F2 of the photoresist layer 16 is attached to cover the third and fourth semiconductor chips C3 and C4.

The second surface 16F2 of the photoresist layer 16 may completely cover the exposed portions of the third and fourth semiconductor chips C3 and C4 and the top surface of the second wiring structure 130. In addition, the photoresist layer 16 may be conformally deformed according to a step difference between the third and fourth semiconductor chips C3 and C4.

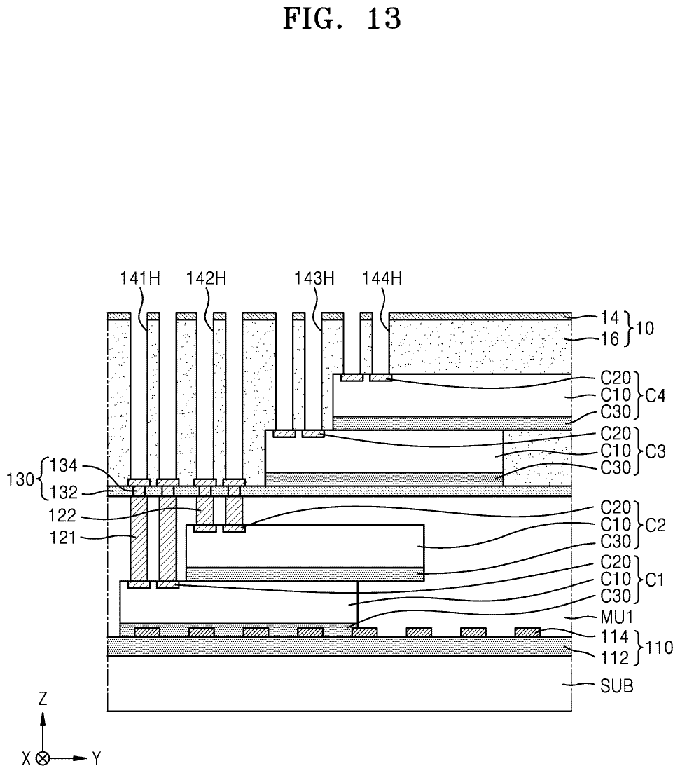

Referring to FIG. 13, the base film 12 is removed from the photoresist film 10, and the photoresist film 10 is exposed and developed to form a plurality of first to fourth openings 141H, 142H, 143H, and 144H in an outer region of the second wiring structure 130 and the outer regions of the third and fourth semiconductor chips C3 and C4.

The plurality of first and second openings 141H and 142H having a high aspect ratio may be regularly formed in the outer region of the second wiring structure 130 by one-time exposure and development processes.

In embodiments, the plurality of second conductive patterns 134 connected to the plurality of first and second lower conductive posts 121 and 122 may be exposed on bottoms of the plurality of first and second openings 141H and 142H. Each first and second opening of the plurality of first and second openings 141H and 142H may have a relatively large height to pass through an entire depth of the photoresist film 10. In embodiments, each first and second opening of the plurality of first and second openings 141H and 142H may have a relatively high aspect ratio that is a height in the vertical direction (for example, a height in the Z direction) to a width in a horizontal direction (for example, a width in a Y direction). In embodiments, each first and second opening of the plurality of first and second openings 141H and 142H may have an aspect ratio greater than 8, or greater than 9, or greater than 10.

In embodiments, as the photoresist film 10 includes the capping layer 14 having a high refractive index on the photoresist layer 16, rectilinearity of light irradiated in the exposure process may be improved. Therefore, an atypical defect, in which the width of each first and second opening of the plurality of first and second openings 141H and 142H is locally reduced or a sidewall of each first and second opening of the plurality of first and second openings 141H and 142H is inclined, may be prevented in the exposure process. In addition, in the exposure process, as light is sufficiently irradiated to a bottom of an opening having a high aspect ratio, a not-open defect that may occur when light is not irradiated to a bottom of an opening having a high aspect ratio may be prevented.

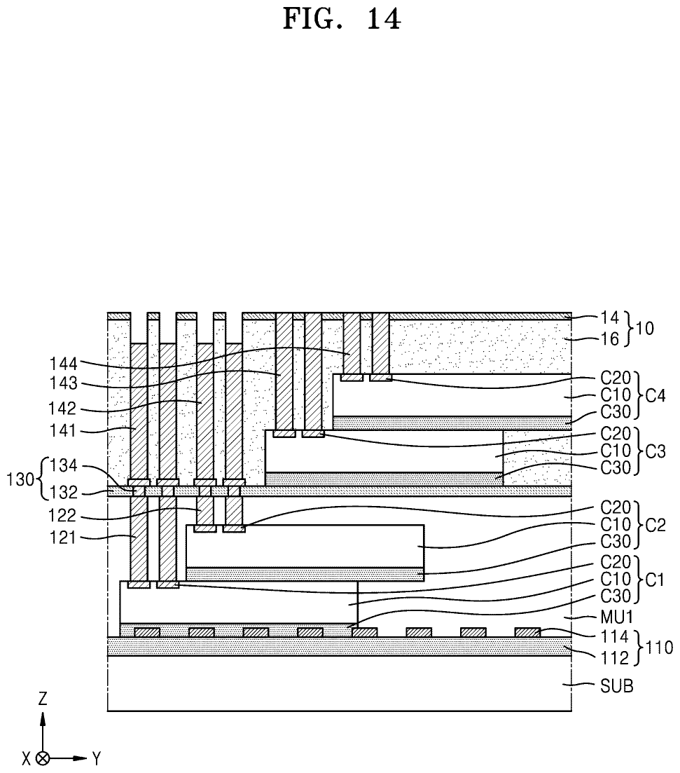

Referring to FIG. 14, the plurality of first to fourth openings 141H, 142H, 143H and 144H are filled with a conductive material to form the plurality of first to fourth upper conductive posts 141, 142, 143, and 144 arranged on the second wiring structure 130 and the third and fourth semiconductor chips C3 and C4.

The plurality of first to fourth upper conductive posts 141, 142, 143, and 144 may be formed by plating. According to the inventive concept, the plurality of first to fourth upper conductive posts 141, 142, 143, and 144 satisfying a desired shape may be formed by one-time exposure and development processes using the photoresist film 10 and a single plating process. In some embodiments, the plating process may be performed with Cu or a Cu alloy. However, the inventive concept is not limited thereto.

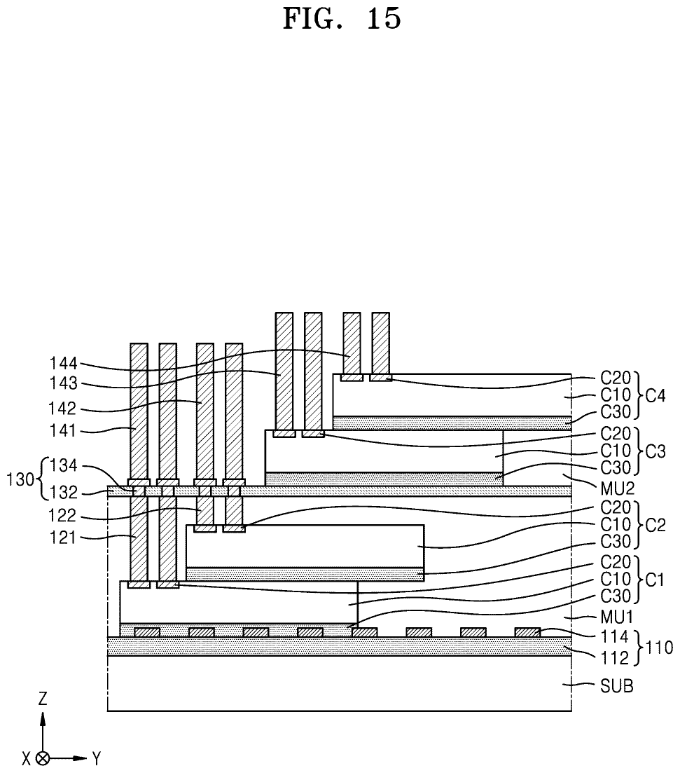

Referring to FIG. 15, the photoresist film 10 is completely removed.

A strip process and/or an ashing process may be performed to remove the photoresist film 10. As the photoresist film 10 is removed, the third and fourth semiconductor chips C3 and C4 and the plurality of first to fourth upper conductive posts 141, 142, 143, and 144 may be exposed to the outside.

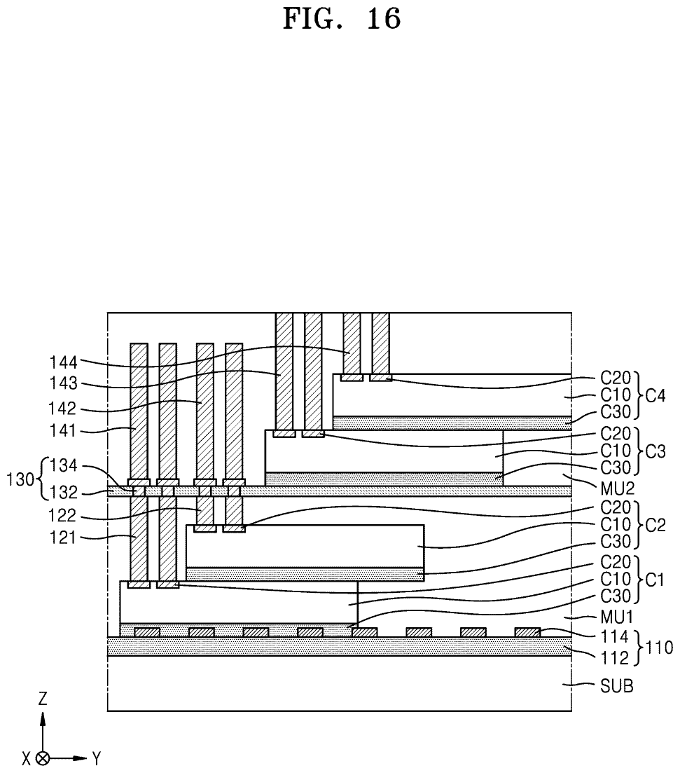

Referring to FIG. 16, the second molding member MU2 covering the second wiring structure 130, the third and fourth semiconductor chips C3 and C4, and the plurality of first and second upper conductive posts 141 and 142 is formed.

The second molding member MU2 is formed on the top surface of the second wiring structure 130 to surround the third and fourth semiconductor chips C3 and C4 and the plurality of first to fourth upper conductive posts 141, 142, 143, and 144, and to protect the third and fourth semiconductor chips C3 and C4 and the plurality of first to fourth upper conductive posts 141, 142, 143, and 144 from an external environment.

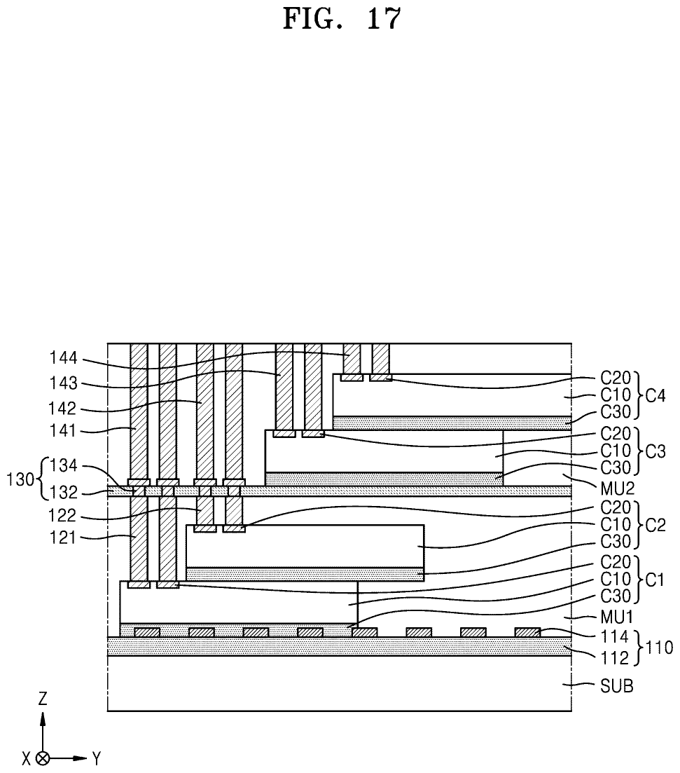

Referring to FIG. 17, part of the second molding member MU2 is removed to completely expose top surfaces of the plurality of first and second upper conductive posts 141 and 142.

For example, an upper portion of the second molding member MU2 may be removed by a chemical mechanical polishing (CMP) process. Accordingly, upper portions of the plurality of first to fourth upper conductive posts 141, 142, 143, and 144 positioned on the second molding member MU2 are also removed so that the second molding member MU2 may have a flat top surface.

Referring again to FIG. 4, the third wiring structure 150 is formed on the second molding member MU2. The third wiring structure 150 may include the third insulating layer 152 and the plurality of third conductive patterns 154.

The plurality of third conductive patterns 154 may be connected to the plurality of first to fourth upper conductive posts 141, 142, 143, and 144 arranged under the third wiring structure 150. For example, the first semiconductor chip C1 may be connected to the outside through the plurality of first lower conductive posts 121 and the plurality of first upper conductive posts 141. In addition, the second semiconductor chip C2 may be connected to the outside through the plurality of second lower conductive posts 122 and the plurality of second upper conductive posts 142. The third semiconductor chip C3 may be connected to the outside through the plurality of third upper conductive posts 143. In addition, the fourth semiconductor chip C4 may be connected to the outside through the plurality of fourth upper conductive posts 144.

Through such a method of manufacturing a semiconductor package, the semiconductor package 100 according to the inventive concept may be manufactured.

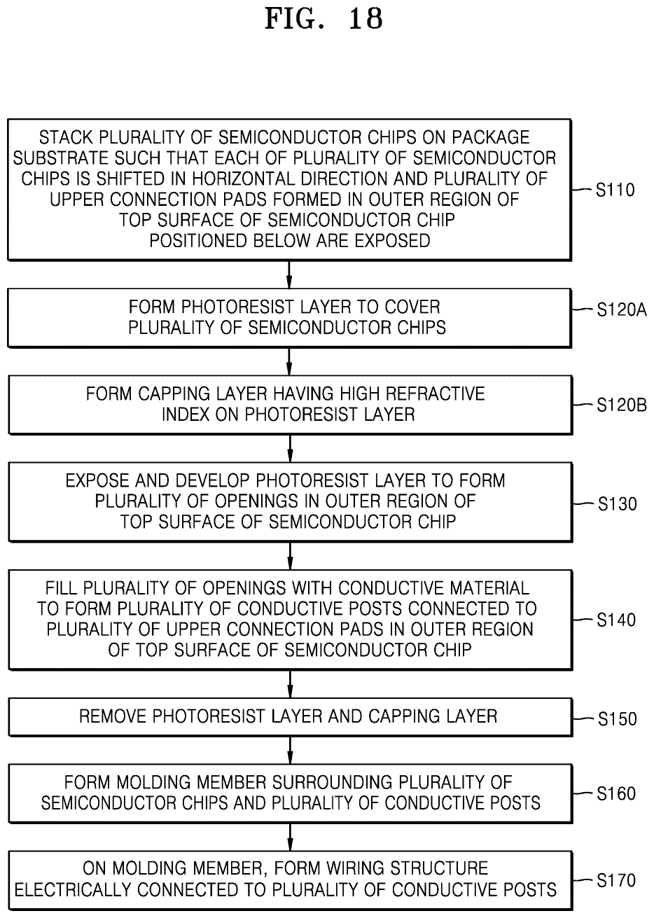

FIG. 18 is a flowchart illustrating a method of manufacturing a semiconductor package according to embodiments.

Referring to FIG. 18, the method of manufacturing a semiconductor package according to embodiments may include operation S110 of stacking a plurality of semiconductor chips on a package substrate such that each semiconductor chip of the plurality of semiconductor chips is shifted in a horizontal direction with respect to other semiconductor chips by a predetermined distance and a plurality of upper connection pads formed in an outer region of a top surface of a semiconductor chip positioned below are exposed, operation S120A of forming a photoresist layer to cover the plurality of semiconductor chips, operation S120B of forming a high refractive index capping layer on the photoresist layer, operation S130 of exposing and developing the photoresist layer to form a plurality of openings in the outer region of the photoresist layer over the top surface of the semiconductor chip, operation S140 of filling the plurality of openings with a conductive material to form a plurality of conductive posts, each conductive post being connected to a corresponding upper connection pad of the plurality of upper connection pads in the outer region of the top surface of a corresponding semiconductor chip from the plurality of semiconductor chips, operation S150 of removing the photoresist layer and the capping layer, operation S160 of forming a molding member surrounding the plurality of semiconductor chips and the plurality of conductive posts, and operation S170 of forming a wiring structure electrically connected to the plurality of conductive posts on the molding member.

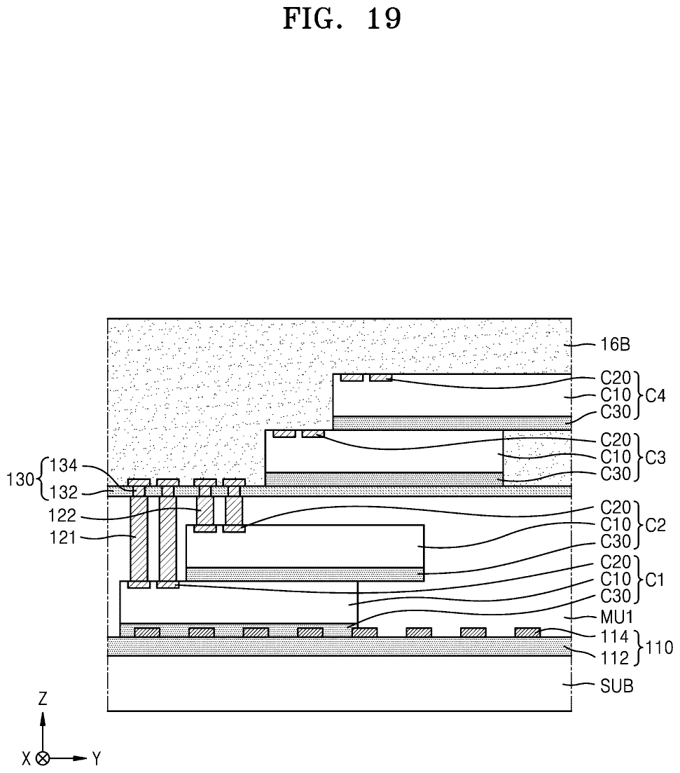

Technical features of each of the herein-described operations S110 to S170 will be described in detail with reference to FIGS. 19 to 21 described herein.

FIGS. 19 to 21 are cross-sectional views illustrating a method of manufacturing a semiconductor package according to embodiments.

First, the processes described with reference to FIGS. 6 to 10 may be performed to shift each semiconductor chip of the plurality of semiconductor chips in the horizontal direction by a predetermined distance on the package substrate and to sequentially stack the plurality of semiconductor chips so that the plurality of upper connection pads formed in the outer region of the top surface of the semiconductor chip positioned below are exposed in operation S110 (refer to FIG. 18).

Referring to FIG. 19, a photoresist layer 16B may be formed on the package substrate SUB to cover the first to fourth semiconductor chips C1, C2, C3, and C4.

In embodiments, the photoresist layer 16B may be formed by a spin coating process. In embodiments, the photoresist layer 16B may be formed to have a sufficiently large thickness to cover the third and fourth semiconductor chips C3 and C4 mounted on the second wiring structure 130. In embodiments, the photoresist layer 16B may be formed to a thickness of 5 micrometers to 500 micrometers, or 25 micrometers to 450 micrometers, or 50 micrometers to 400 micrometers.

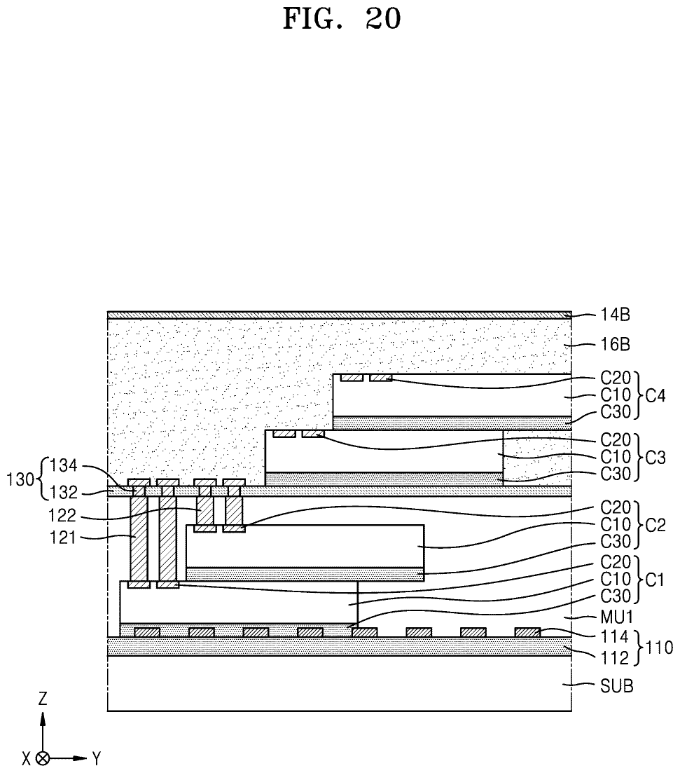

Referring to FIG. 20, a capping layer 14B may be formed on the photoresist layer 16B.

In embodiments, the capping layer 14B may be formed by a CVD process. In embodiments, the capping layer 14B may be formed by a CVD process using sulfur molecules and allyl monomers as precursors. In embodiments, the capping layer 14B may be formed by a radical reaction between Ss molecules and allyl monomers. In the CVD process, heat may be supplied to the reaction chamber using a heater or a hot filament to generate a radical reaction of Ss molecules. Ring-shaped Ss molecules may be evaporated by a heater or a hot filament to generate sulfur radicals from the Ss molecules, and a polymer material including sulfur may be generated through a polymerization reaction between an allyl monomer and a sulfur radical.

In embodiments, the capping layer 14B may be formed to a thickness in a range of 5 nanometers to 5 micrometers, or 50 nanometers to 4 micrometers, or 100 nanometers to 3 micrometers.

In embodiments, the capping layer 14B may include or be a material having a higher refractive index than a photoresist material. In embodiments, the capping layer 14B may have a refractive index greater than 1.5, 1.7, or 1.9. In some embodiments, the capping layer 14B formed by a radical reaction between sulfur and an allyl monomer may have a refractive index of 1.95. In some embodiments, the capping layer 14B may have a refractive index in a range of 1.5 to 2.0, or 1.7 to 1.98.

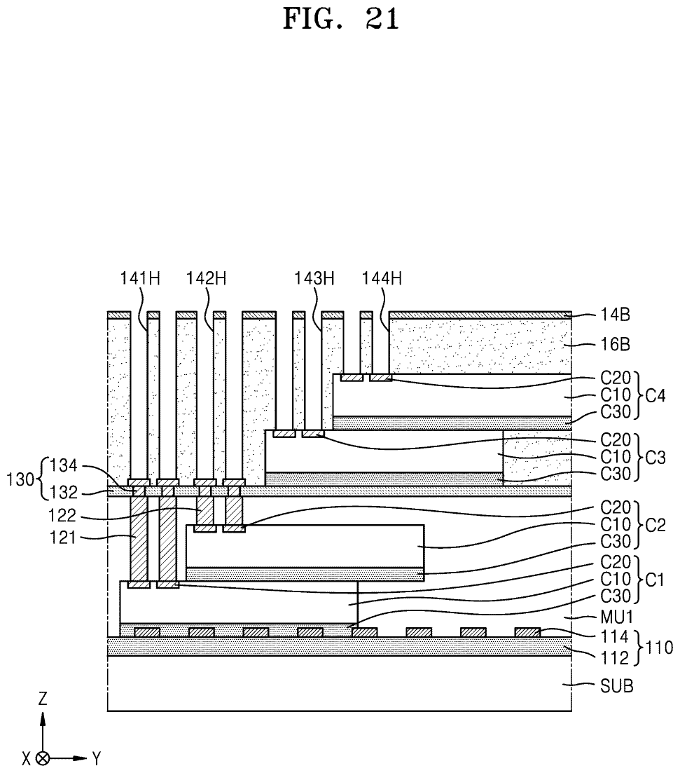

Referring to FIG. 21, the photoresist layer 16 is exposed and developed to form the plurality of first to fourth openings 141H, 142H, 143H, and 144H in the outer region of the second wiring structure 130 and the outer regions of the third and fourth semiconductor chips C3 and C4.

The plurality of first and second openings 141H and 142H having a high aspect ratio may be regularly formed in the outer region of the second wiring structure 130 by one-time exposure and development processes.

Thereafter, the semiconductor package may be completed by performing the processes described with reference to FIGS. 14 to 17.

In embodiments, as the capping layer 14B having a high refractive index is formed on the photoresist layer 16B, rectilinearity of light irradiated in the exposure process may be improved. Therefore, an atypical defect, in which the width of each first and second opening of the plurality of first and second openings 141H and 142H is locally reduced or a sidewall of each first and second opening of the plurality of first and second openings 141H and 142H is inclined, may be prevented in the exposure process. In addition, in the exposure process, as light is sufficiently irradiated to a bottom of an opening having a high aspect ratio, a not-open defect that may occur when light is not irradiated to a bottom of an opening having a high aspect ratio may be prevented.

In the method of manufacturing a semiconductor package according to the inventive concept, a photoresist film including a capping layer having a high refractive index may be used to form a conductive post having a high aspect ratio by one-time exposure, development, and plating processes. Therefore, reliability of the semiconductor package may be increased and manufacturing cost of the semiconductor package may be reduced.

While the inventive concept has been particularly shown and described with reference to embodiments thereof, it will be understood that various changes in form and details may be made therein without departing from the spirit and scope of the following claims.

What is claimed is:

1. A method of manufacturing a semiconductor package comprising:
stacking a plurality of semiconductor chips on a package substrate such that each semiconductor chip of the plurality of semiconductor chips is shifted in a horizontal direction with respect to each other semiconductor chip of the plurality of semiconductor chips, by a predetermined distance and a plurality of upper connection pads formed in an outer region of a top surface of a corresponding semiconductor chip from the plurality of semiconductor chips positioned below are exposed;
covering the package substrate with a photoresist film to surround side and top surfaces of each semiconductor chip of the plurality of semiconductor chips, the photoresist film including a photoresist layer and a capping layer arranged on a top surface of the photoresist layer;
exposing and developing the photoresist film to form a plurality of openings in the photoresist film over the outer region of the top surface of each semiconductor chip of the plurality of semiconductor chips;
filling the plurality of openings with a conductive material to form a plurality of conductive posts, each conductive post of the plurality of conductive posts being connected to a corresponding upper connection pad of the plurality of upper connection pads in the outer region of the top surface of a corresponding semiconductor chip of the plurality of semiconductor chips;
removing the photoresist film; and
forming a molding member surrounding the plurality of semiconductor chips and the plurality of conductive posts,
wherein the capping layer comprises a polymer material including sulfur.

2. The method of claim 1, wherein the capping layer is formed by a radical reaction between sulfur molecules and allyl monomers.

3. The method of claim 1, wherein the capping layer has a refractive index greater than a refractive index of the photoresist layer.

4. The method of claim 1, wherein the capping layer has a refractive index of greater than 1.5.

5. The method of claim 1, wherein the photoresist layer comprises a negative photoresist material or a positive photoresist material.

6. The method of claim 1, wherein the capping layer has a thickness of 5 nanometers to 5 micrometers.

7. The method of claim 1, wherein the photoresist layer has a thickness of 5 micrometers to 500 micrometers.

8. The method of claim 1, wherein a ratio of a height in a vertical direction to a width in a horizontal direction of each opening of the plurality of openings is greater than 8.

9. The method of claim 1, the covering of the package substrate with the photoresist film comprises:
preparing a dry photoresist film in which the capping layer and the photoresist layer are attached onto a base film and a release film is attached onto the photoresist layer;
removing the release film from the dry photoresist film;
attaching the dry photoresist film onto the plurality of semiconductor chips so that the photoresist layer covers the plurality of semiconductor chips; and
removing the base film from the dry photoresist film and exposing a top surface of the capping layer.

10. The method of claim 9, wherein the base film comprises at least one material selected from the group consisting of polyolefin (PO), polyethylene terephthalate (PET), polyether ether ketone (PEEK), polymethyl methacrylate (PMA), and polyimide (PI).

11. The method of claim 9, wherein the capping layer has a refractive index of 1.5 to 2.0.

12. The method of claim 1, the covering of the package substrate with the photoresist film comprises:
forming a photoresist layer covering the plurality of semiconductor chips, on the package substrate; and
forming the capping layer on the photoresist layer.

13. The method of claim 12, wherein the forming of the photoresist layer is performed by a spin coating process.

14. The method of claim 12, wherein the forming of the capping layer is performed by a chemical vapor deposition (CVD) process.

15. The method of claim 14, wherein, in the forming of the capping layer, a polymer material layer including sulfur is formed by a radical reaction between sulfur molecules and allyl monomers.

16. A method of manufacturing a semiconductor package comprising:
stacking a plurality of semiconductor chips on a package substrate such that each semiconductor chip of the plurality of semiconductor chips is shifted in a horizontal direction with respect to each other semiconductor chip of the plurality of semiconductor chips, by a predetermined distance and a plurality of upper connection pads formed in an outer region of a top surface of a corresponding semiconductor chip from the plurality of semiconductor chips positioned below are exposed;
preparing a photoresist film including a base film, a capping layer, a photoresist layer and a release film that are sequentially stacked, the capping layer including a polymer material layer including sulfur;
removing the release film from the photoresist film;
attaching the photoresist film onto the package substrate so that the photoresist layer covers the plurality of semiconductor chips;
exposing and developing the photoresist film to form a plurality of openings in the photoresist film over the outer region of the top surface of each semiconductor chip of the plurality of semiconductor chips;
filling the plurality of openings with a conductive material to form a plurality of conductive posts, each conductive post of the plurality of conductive posts being connected to a corresponding upper connection pad of the plurality of upper connection pads in the outer region of the top surface of the corresponding semiconductor chip of the plurality of semiconductor chips;
removing the photoresist film;
forming a molding member surrounding the plurality of semiconductor chips and the plurality of conductive posts; and
forming a wiring structure electrically connected to the plurality of conductive posts, on the molding member.

17. The method of claim 16, wherein the capping layer has a refractive index of 1.5 to 2.0.

18. The method of claim 16, wherein the capping layer has a thickness of 5 nanometers to 5 micrometers, and
wherein the photoresist layer has a thickness in a range of 5 micrometers to 500 micrometers.

19. The method of claim 16, wherein the base film comprises at least one material selected from the group consisting of PO, PET, PEEK, PMA, and PI, and
wherein the release film comprises at least one material selected from the group consisting of PO, PET, PEEK, PMA, and PI.

20. A method of manufacturing a semiconductor package comprising:
stacking a plurality of semiconductor chips on a package substrate such that each semiconductor chip of the plurality of semiconductor chips is shifted in a horizontal direction with respect to each other semiconductor chip of the plurality of semiconductor chips, by a predetermined distance and a plurality of upper connection pads formed in an outer region of a top surface of a corresponding semiconductor chip from the plurality of semiconductor chips positioned below are exposed;
preparing a photoresist film including a base film, a capping layer, a photoresist layer, and a release film that are sequentially stacked;
removing the release film from the photoresist film;
attaching the photoresist film onto the package substrate so that the photoresist layer covers the plurality of semiconductor chips;
exposing and developing the photoresist film to form a plurality of openings in the photoresist film over the outer region of the top surface of the semiconductor chip, wherein a ratio of a height in a vertical direction to a width in a horizontal direction of each opening of the plurality of openings is greater than 8;
filling the plurality of openings with a conductive material to form a plurality of conductive posts, each conductive post of the plurality of conductive posts being connected to a corresponding upper connection pad of the plurality of upper connection pads in the outer region of the top surface of a corresponding semiconductor chip of the plurality of semiconductor chips;
removing the photoresist film;
forming a molding member surrounding the plurality of semiconductor chips and the plurality of conductive posts; and
forming a wiring structure electrically connected to the plurality of conductive posts, on the molding member, wherein the capping layer comprises a polymer material layer including sulfur, wherein the capping layer is formed by a radical reaction between sulfur molecules and allyl monomers, wherein the capping layer has a refractive index in a range of 1.5 to 2.0, and
wherein the capping layer has a thickness in a range of 5 nanometers to 5 micrometers.
